(19) United States
(12) Patent Application Publication
(10) Pub. No.: US 2026/0333833 A1
(43) Pub. Date: Oct. 22, 2026

(54) METHODS OF APPLYING STRAIN TO CFET AND THE STRUCTURES THEREOF

(71) Applicant: Taiwan Semiconductor Manufacturing Co., Ltd., Hsinchu (TW)

(72) Inventors: Che Chi Shih, Taoyuan City (TW); Ku-Feng Yang, Baoshan Township (TW); Kuan-Kan Hu, Hsinchu (TW); Szuya Liao, Zhubei (TW)

(21) Appl. No.: 19/721,193

(22) Filed: Jun. 26, 2026

Related U.S. Application Data
(63) Continuation of application No. 19/096,029, filed on Mar. 31, 2025.
(60) Provisional application No. 63/727,779, filed on Dec. 4, 2024.

(51) Int. Cl. H10D 84/01; H10D 84/85; H10W 72/00; H10W 72/30

(52) U.S. Cl. CPC H10D 84/017; H10D 84/0167; H10D 84/851; H10D 84/856; H10W 72/01338; H10W 72/07331; H10W 72/353

(57) ABSTRACT

A method includes forming a first wafer and a second wafer. The formation of the first wafer comprises forming a first semiconductor layer over a first substrate, and depositing a first dielectric layer comprising a first top portion over the first semiconductor layer. The first dielectric layer comprises a first dielectric material. The formation of the second wafer comprises forming a second semiconductor layer over a second substrate, and depositing a second dielectric layer comprising a second top portion over the second semiconductor layer. The second dielectric layer comprises a second dielectric material different from the first dielectric material. The second wafer is bonded to the first wafer to form a composite wafer, wherein the first dielectric layer is bonded to and joined to the second dielectric layer. A complementary field-effect transistor is formed based on the composite wafer.

### PRIORITY CLAIM AND CROSS-REFERENCE

This application is a continuation of U.S. patent application Ser. No. 19/096,029, filed Mar. 31, 2025, and entitled “METHODS OF APPLYING STRAIN TO CFET AND THE STRUCTURES THEREOF,” which claims the benefit of U.S. Provisional Application No. 63/727,779, filed on Dec. 4, 2024, and entitled “Method for Fabricating Semiconductor Device,” which application is hereby incorporated herein by reference.

### BACKGROUND

Semiconductor devices are used in a variety of electronic applications such as personal computers, cell phones, digital cameras, and other electronic equipment. Semiconductor devices are typically fabricated by sequentially depositing insulating or dielectric layers, conductive layers, and semiconductor layers over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. As the minimum feature sizes are reduced, however, additional problems arise and should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-7 illustrate the cross-sectional views of intermediate stages in the formation of a composite wafer with internal strain in accordance with some embodiments.

FIGS. 8-10 illustrate the cross-sectional views of intermediate stages in the formation of a wafer in accordance with alternative embodiments.

FIGS. 11-17 illustrate the cross-sectional views of intermediate stages in the formation of Complementary Field-Effect Transistors (CFETs) in accordance with some embodiments.

FIG. 18 illustrates the profiles of densities and Si/N atomic ratios of strain-applying bond layers in a CFET that comprises a PFET and an NFET over the PFET in accordance with some embodiments.

FIG. 19 illustrates the profiles of densities and Si/N atomic ratios of strain-applying bond layers in a CFET that comprises an NFET and a PFET over the NFET in accordance with some embodiments.

FIG. 20 illustrates a process flow of forming a composite wafer and a CFET in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “underlying,” “below,” “lower,” “overlying,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Complementary Field-Effect Transistors (CFETs) including upper FETs (alternatively referred to as transistors) and lower FETs and the formation processes are provided. In accordance with some embodiments, the formation process includes forming a lower wafer, and depositing a lower dielectric layer (lower bond layer) on the lower wafer. The lower dielectric layer applies a first strain to the lower wafer. An upper wafer is also formed, and an upper dielectric layer (upper bond layer) is deposited on the upper wafer. The upper dielectric layer applies a second strain opposite to the first strain to the upper wafer.

The upper wafer is bonded to the lower wafer to form a composite wafer through the bonding of the upper dielectric layer to the lower dielectric layer. CFETs are then formed in the composite wafer, wherein upper FETs are formed in the upper wafer, and lower FETs are formed in the lower wafer. The first strain is desirable by the lower FETs, and the second strain is desirable by the upper FETs. The upper dielectric layer and the lower dielectric layer thus have the function of applying desirable strains to the respective upper FETs and lower FETs, and have the function of improving the drive currents of the upper FETs and the lower FETs.

Although the example embodiments use GAA FETs as the upper FETs and the lower FETs, the embodiments may also be applied to the CFETs comprising other FETs such as Fin Field-Effect Transistors (FinFETs), planar transistors, the like, or the combinations of the GAA FETs, FinFETs, and planar FETs. Throughout the description, the terms “FET” and “transistor” are used interchangeably. The Embodiments discussed herein are to provide examples to enable making or using the subject matter of this disclosure, and a person having ordinary skill in the art will readily understand modifications that can be made while remaining within contemplated scopes of different embodiments. Throughout the various views and illustrative embodiments, like reference numbers are used to designate like elements. Although method embodiments may be discussed as being performed in a particular order, other method embodiments may be performed in any logical order.

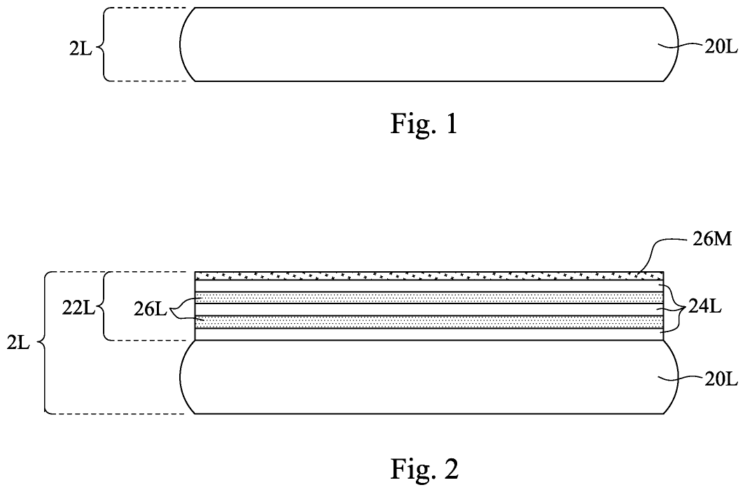

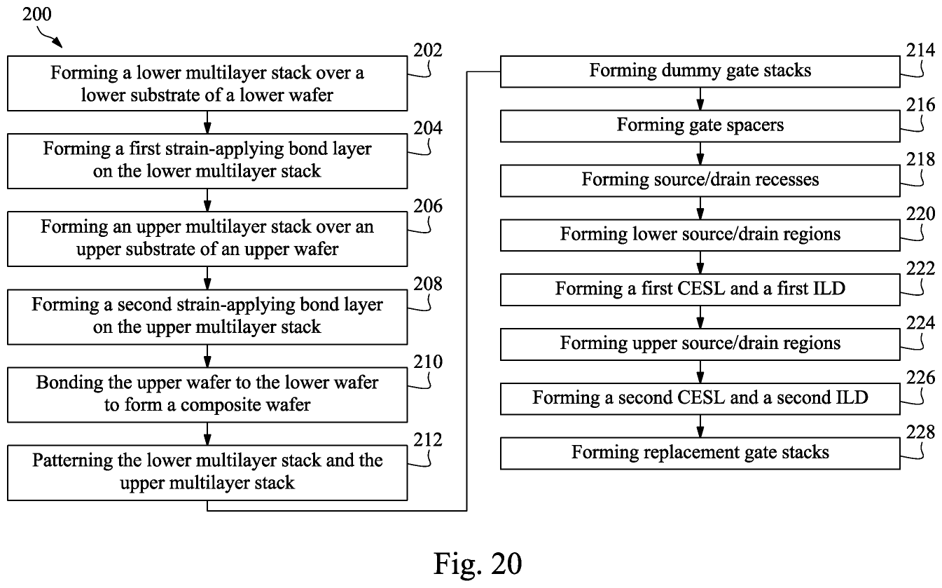

FIGS. 1-17 illustrate the cross-sectional views of intermediate stages in the formation of composite wafers and CFETs in accordance with some embodiments. The corresponding processes are also reflected schematically in the process flow 200 as shown in FIG. 20.

Referring to FIG. 1, wafer 2L, which includes substrate 20L, is provided. In accordance with some embodiments, substrate 20L is a bulk substrate formed of a homogeneous semiconductor material such as silicon. In accordance with alternative embodiments, substrate 20L may be a composite substrate having a composite structure. The composite structure may include a first semiconductor layer and a second semiconductor layer, which may be silicon layers, and a stop layer between the first semiconductor layer and the second semiconductor layer. The stop layer may be formed of or comprise a semiconductor material such as silicon germanium. Alternatively, the stop layer may comprise a dielectric material such as silicon nitride, silicon oxide, or the like.

Referring to FIG. 2, (lower) multilayer stack 22L is formed over the substrate 20L. The respective process is illustrated as process 202 in the process flow 200 as shown in FIG. 20. The multilayer stack 22L includes alternating dummy semiconductor layers 24L and lower semiconductor layers 26L. Lower semiconductor layers 26L are for forming lower FETs. In the subsequent discussion, it is assumed that the lower FETs that are formed in subsequent processes are p-type FETs, and the upper FETs that are formed in subsequent processes are n-type FETs. In accordance with alternative embodiments, the lower FETs may be n-type FETs, and upper FETs may be p-type FETs.

Appropriate wells (not separately illustrated) may be formed in lower semiconductor layers 26L. For example, lower semiconductor layers 26L may be in-situ doped (when epitaxially grown) and/or implanted to a desirable conductivity type. For example, when the lower FETs are p-type FETs, the wells may be doped with an n-type dopant such as phosphorous, arsenic, and/or the like.

In the illustrated example, the multilayer stack 22L includes three dummy semiconductor layers 24L and two lower semiconductor layers 26L. It should be appreciated that the multilayer stack 22L may include any number of the dummy semiconductor layers 24L and the lower semiconductor layers 26L. Each layer of the multilayer stack 22L may be grown by a process such as Vapor Phase Epitaxy (VPE) or Molecular Beam Epitaxy (MBE), deposited by a process such as a Chemical Vapor Deposition (CVD) process or an Atomic Layer deposition (ALD) process, or the like.

The dummy semiconductor layers 24L are formed of a first semiconductor material, and the lower semiconductor layers 26L are formed of a second semiconductor material different from the first semiconductor material. The first and second semiconductor materials may be selected from the candidate semiconductor materials of the substrate 20L. The first and second semiconductor materials have a high etching selectivity to one another. As such, in subsequent processes, the dummy semiconductor layer 24L may be removed at a faster rate than the lower semiconductor layers 26L.

In some embodiments, dummy semiconductor layers 24L are formed of or comprise silicon germanium, and lower semiconductor layers 26L are formed of silicon. The thicknesses of lower semiconductor layers 26L may be the same as each other or different from each other. The thicknesses of dummy semiconductor layers 24L may be the same as each other or different from each other.

In accordance with some embodiments, as shown in FIG. 2, multilayer stack 22L further includes semiconductor layer 26M, which is deposited over the top one of the dummy semiconductor layers 24L. Semiconductor layer 26M may be formed of a material that is the same as the material of lower semiconductor layers 26L. For example, semiconductor layer 26M may be formed of or comprise silicon. Alternatively, semiconductor layer 26M may be formed of or comprise silicon germanium, with the germanium atomic percentage being lower than that of dummy semiconductor layers 24L.

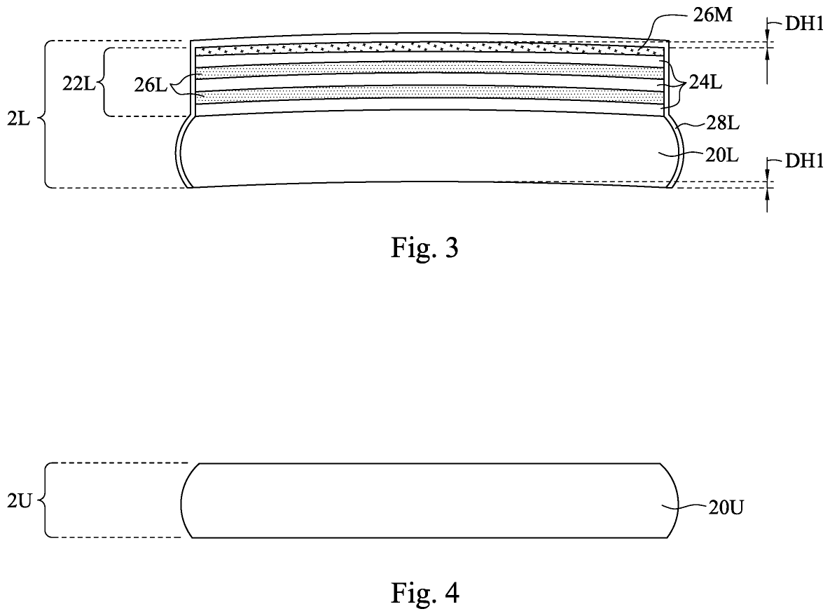

In accordance with alternative embodiments, semiconductor layer 26M is not formed, and the subsequently formed dielectric layer 28L (FIG. 3) is formed over and in contact with the topmost semiconductor layer 24L in multilayer stack 22L. In accordance with some embodiments, the thickness of semiconductor layer 26M may be smaller than the thicknesses of dummy semiconductor layers 24L and the thicknesses of lower semiconductor layers 26L.

Referring to FIG. 3, (lower) dielectric layer 28L is deposited on lower multilayer stack 22L. Dielectric layer 28L is alternatively referred to as a bond layer or a strain-applying bond layer. The respective process is illustrated as process 204 in the process flow 200 as shown in FIG. 20. Dielectric layer 28L may be in contact with semiconductor layer 26M, or in contact with the topmost dummy semiconductor layer 24L if semiconductor layer 26M is not formed. Dielectric layer 28L may comprise a dielectric material, and may have an amorphous structure or a crystalline structure.

In accordance with some embodiments, dielectric layer 28L may be formed through a conformal deposition process such as a Plasma-Enhanced Atomic Layer Deposition (PEALD) process, a thermal Atomic Layer Deposition (ALD) process, or the like. In the embodiments in which the PEALD is used, the wafer temperature may be lower than about 100 °C, and may be in the range between about 100 °C and about 200 °C. In the embodiments in which thermal ALD is used, the wafer temperature may be higher than about 100 °C, and may be in the range between about 200 C and about 700 °C.

In accordance with some embodiments, dielectric layer 28L comprises silicon nitride (SiN). In accordance with alternative embodiments, dielectric layer 28L comprises other applicable materials such as silicon oxynitride (SiON), silicon carbo-nitride (SiCN), or the like, or combinations thereof. The material is selected along with the formation processes, so that a desirable strain is generated in dielectric layer 28L, which strain is applied to the lower multilayer stack 22L, and to the channel regions of the subsequently formed lower FETs.

In accordance with some embodiments in which dielectric layer 28L comprises silicon nitride, the respective precursors may include a silicon-containing precursor such as silane (SiH₄), di-silane (Si₂H₆), dichlorosilane (SiCl₂H₂, DCS), or the like, or combinations thereof. The precursors further comprise a nitrogen-containing precursor such as ammonia (NH₃), nitrogen (N₂), and/or the like. The formation process may include a plurality of cycles, each including a pulsing process and a purging process of the silicon-containing precursor, and a pulsing process and a purging process of the nitrogen-containing precursor.

In accordance with some embodiments, dielectric layer 28L is controlled to be not too thick and not too thin. For example, the thickness of dielectric layer 28L may be in the range between about 5 nm and about 20 nm. When dielectric layer 28L is too thin such as thinner than about 5 nm, the strain it applies may not be adequately high. When dielectric layer 28L is too thick such as thicker than about 20 nm, in the subsequent formation of CFETs, the aspect ratio of source/drain recesses 46 (FIG. 12) may be too high, and it is difficult to form features filling the recesses 46.

In accordance with some embodiments, the lower FETs are PFETs, whose channel regions prefer compressive strains. Accordingly, dielectric layer 28L have compressive strains (and is referred to as a compressive dielectric layer), and applies a compressive strain to multilayer stack 22L. In accordance with some embodiments, the compressive strain may be achieved by adjusting the material, the formation process, and/or the properties of dielectric layer 28L.

In accordance with some embodiments in which dielectric layer 28L comprises silicon nitride, the density may be increased, and the silicon-to-nitrogen atomic ratio may be reduced to adjust the strain to be more compressive. For example, increasing the density and reducing the silicon-to-nitrogen atomic ratio of dielectric layer 28L may result in the increase the magnitude of the compressive strain, the change of a tensile strain into a compressive strain, or the reduction of the magnitude of a tensile strain.

Accordingly, the dielectric layers 28L that has the compressive strain (for PFETs) has a relatively high density and a relatively low silicon-to-nitrogen atomic ratio. For example, the density of the dielectric layer 28L having compressive strain may be greater than about 2.5 g/cm³, and may be in the range between about 2.5 g/cm³ and about 3.5 g/cm³. When the density of dielectric layers 28L is out of this range, the strain may not be compressive. The silicon-to-nitrogen atomic ratio may be in the range between 0.1 and about 0.8. When the silicon-to-nitrogen atomic ratio is out of this range, the strain may not be compressive. The corresponding compressive strain in the dielectric layer 28L (and applied to the multilayer stack 22L) may be greater than 0 GPa and smaller than about 1 GPa.

After the deposition of dielectric layer 28L, the wafer temperature is reduced, for example, to the room temperature. To make the strain to be more compressive, the temperature dropping rate after the deposition of the dielectric layers 28L may be controlled, and a greater temperature dropping rate may result in a more compressive stress. For example, the temperature dropping rate after the formation of dielectric layers 28L may be greater than about 200 °C/minute, and may be in the range between about 100 °C/minute and about 1,000 °C/minute.

In accordance with some embodiments, dielectric layers 28L comprises a top portion overlapping multilayer stack 22L, and sidewall portions on the sidewalls of multilayer stack 22L. The dielectric layers 28L may or may not extend on the sidewalls of substrate 20L.

In accordance with some embodiments, as a result of the formation of the dielectric layer 28L that has the compressive strain, wafer 2L may have a warpage, with the center portion of the wafer 2L being higher than the edge portions of the wafer 2L. Depending on the size of the wafer 2L and the strain applied by dielectric layer 28L, the height difference DH1 may be in the range between about 1 μm and about 20 μm.

Referring to FIG. 4, wafer 2U, which includes substrate 20U, is provided. In accordance with some embodiments, substrate 20U is a bulk substrate formed of a homogeneous semiconductor material such as silicon. In accordance with alternative embodiments, substrate 20U may be a composite substrate having a composite structure. The composite structure may include a first semiconductor layer and a second semiconductor layer, which may be silicon layers, and a stop layer between the first semiconductor layer and the second semiconductor layer. The stop layer may be formed of or comprise a semiconductor material such as silicon germanium. Alternatively, the stop layer may comprise a dielectric material such as silicon nitride, a silicon oxide, or the like.

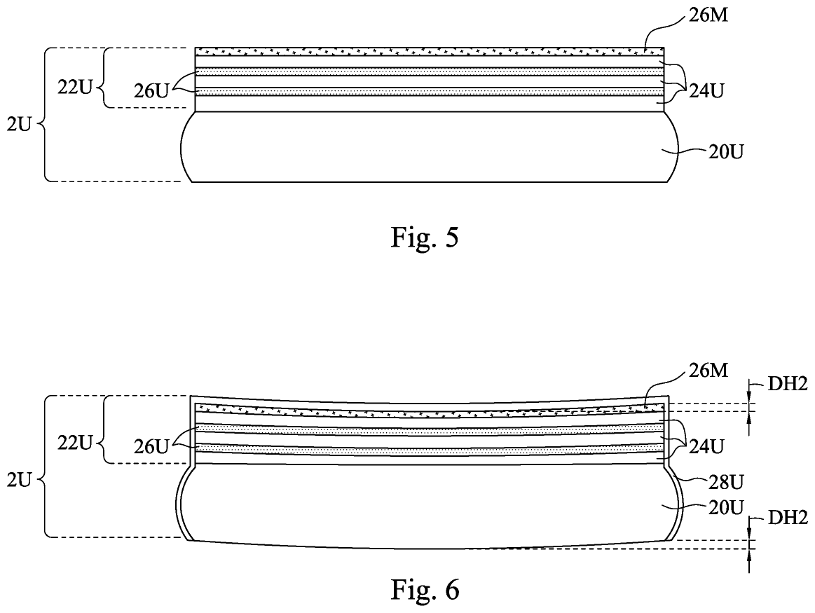

Referring to FIG. 5, (upper) multilayer stack 22U is formed over the substrate 20U. The respective process is illustrated as process 206 in the process flow 200 as shown in FIG. 20. The multilayer stack 22U includes alternating dummy semiconductor layers 24U and upper semiconductor layers 26U. Upper semiconductor layers 26U are for forming upper FETs. In the subsequent discussion, it is assumed that the upper FETs are NFETs.

Appropriate wells (not separately illustrated) may be formed in upper semiconductor layers 26U. For example, upper semiconductor layers 26U may be in-situ doped (when epitaxially grown) and/or implanted to desirable conductivity types. For example, when the upper FETs are n-type FETs, the wells may be doped with a p-type dopant such as boron, indium, and/or the like.

In the illustrated example, the multilayer stack 22U includes two dummy semiconductor layers 24U and one upper semiconductor layer 26U. It should be appreciated that the multilayer stack 22U may include any number of dummy semiconductor layers 24U and the upper semiconductor layers 26U. Each layer of the multilayer stack 22U may be grown by a process such as VPE, MBE, CVD, ALD, or the like.

The material of dummy semiconductor layers 24U is different from the material of upper semiconductor layers 26U in order to have an adequate etching selectivity. In some embodiments, dummy semiconductor layers 24U are formed of or comprise silicon germanium, and upper semiconductor layers 26U are formed of or comprise silicon.

In accordance with some embodiments, as shown in FIG. 5, multilayer stack 22U further includes semiconductor layer 26M, which is deposited over the top one of the dummy semiconductor layers 24U. Semiconductor layer 26M may be formed of a material that is the same as the material of upper semiconductor layers 26U. For example, semiconductor layer 26M may be formed of or comprise silicon. In accordance with alternative embodiments, semiconductor layer 26M is not formed, and the subsequently formed dielectric layer 28U (FIG. 6) is formed over and in contact with the topmost semiconductor layer 24U in multilayer stack 22U. In accordance with some embodiments, the thickness of semiconductor layer 26M may be smaller than the thicknesses of dummy semiconductor layers 24U and the thickness of upper semiconductor layer 26U.

Referring to FIG. 6, (upper) dielectric layer 28U is deposited on multilayer stack 22U. Dielectric layer 28U is also referred to as a bond layer or a strain-applying bond layer. The respective process is illustrated as process 208 in the process flow 200 as shown in FIG. 20. Dielectric layer 28U may be in contact with semiconductor layer 26M, or in contact with the topmost dummy semiconductor layer 24U if semiconductor layer 26M is not formed. Dielectric layer 28U may comprise a dielectric material, and may have an amorphous structure or a crystalline structure.

In accordance with some embodiments, dielectric layer 28U may be formed through a conformal deposition process such as a PEALD process, a thermal ALD process, or the like. In the embodiments in which the PEALD is used, the wafer temperature may be lower than about 100 °C, and may be in the range between about 100 °C and about 200 °C. In the embodiments in which thermal ALD is used, the wafer temperature may be higher than about 100 °C, and may be in the range between about 200 °C and about 700 °C.

In accordance with some embodiments, dielectric layer 28U also comprises silicon nitride (SiN), while other applicable materials such as SiON, SiCN, or the like, or combinations thereof may be used. The material is selected along with the formation processes, so that a desirable strain is generated in dielectric layer 28U, which strain is applied to the underlying multilayer stack 22U, and to the channel regions of the respective upper FETs.

In accordance with some embodiments in which dielectric layer 28U comprises silicon nitride, the respective precursors may include a silicon-containing precursor such as silane (SiH₄), di-silane (Si₂H₆), dichlorosilane (SiCl₂H₂, DCS), or the like, or combinations thereof. The precursors further comprise a nitrogen-containing precursor such as ammonia (NH₃), nitrogen (N₂), and/or the like. The formation process may include a plurality of cycles, each including a pulsing process and a purging process of the silicon-containing precursor, and a pulsing process and a purging process of the nitrogen-containing precursor.

In accordance with some embodiments, dielectric layer 28U is also controlled to be not too thick and not too thin, and the thickness may be in the range between about 5 nm and about 20 nm. When dielectric layer 28U is too thin such as thinner than about 5 nm, the resulting strain may not be high enough. When dielectric layer 28L is too thick such as thicker than about 20 nm, in the subsequent formation of CFETs, the aspect ratio of source/drain recesses 46 (FIG. 12) may be too high, and it is difficult to form features filling the recesses 46.

In accordance with some embodiments, the upper FETs are NFETs, whose channel regions prefer tensile strains. Accordingly, dielectric layer 28U has a tensile strain (and is a tensile dielectric layer), and applies a tensile strain to multilayer stack 22U. In accordance with some embodiments, the tensile strain may be achieved by adjusting the material, the formation process, and/or the properties of dielectric layer 28U.

In accordance with some embodiments in which dielectric layer 28U comprises silicon nitride, the density and the silicon-to-nitrogen atomic ratio may be adjusted to adjust the strain to be more tensile. The dielectric layers 28U that has the tensile strain (for NFETs) may have a relatively low density and a relatively high silicon-to-nitrogen atomic ratio. For example, the density of the dielectric layer 28U that has the tensile strain may be smaller than about 2.7 g/cm³, and may be in the range between about 2.0 g/cm³ and about 2.7 g/cm³. When the density of dielectric layers 28U is out of this range, the strain may not be tensile.

The silicon-to-nitrogen atomic ratio of dielectric layer 28U may be in the range between 0.5 and about 1.0. When the silicon-to-nitrogen atomic ratio of dielectric layers 28U is out of this range, the strain may not be tensile. The corresponding tensile strain in the dielectric layer 28U and applied to the underlying multilayer stack 22U may be greater than −1 GPa and smaller than about 0 GPa.

After the deposition of dielectric layer 28U, the wafer temperature is reduced, for example, to the room temperature. To make the strain in dielectric layer 28U to be more tensile, the temperature dropping rate after the deposition of the dielectric layers 28U may be controlled, and a lower temperature dropping rate may result in a more tensile stress. The temperature dropping rate of dielectric layers 28U may accordingly be smaller than the temperature dropping rate of dielectric layers 28L. For example, the temperature dropping rate of wafer 2U may be lower than about 600 °C/minute, and may be in the range between about 10 °C/minute and about 300 °C/minute.

As a comparison of dielectric layers 28U and 28L, dielectric layer 28L may have a higher density than dielectric layer 28U, for example, with a density difference being greater than about 0.3 g/cm³, and possibly between about 0.5 g/cm³, and about 1.5 g/cm³. Dielectric layer 28L may also have a lower silicon-to-nitrogen atomic ratio than dielectric layer 28U, for example, with a difference being greater than about 0.2, and possibly between about 0.4 and about 0.9. After their formation, during which the wafers 2L and 2U are heated, wafer 2L (and dielectric layer 28L) may also have a greater wafer temperature dropping rate (after the deposition) than wafer 2U (and dielectric layer 28U), for example, with a difference being greater than about 200 °C/minute, and possibly between about 200 °C/minute and about 500 °C/minute.

In accordance with some embodiments, dielectric layers 28U comprises a top portion overlapping multilayer stack 22U, and sidewall portions on the sidewalls of multilayer stack 22U. The dielectric layers 28U may or may not extend on the sidewalls of substrate 20U.

In accordance with some embodiments, as a result of the formation of the dielectric layer 28U that has the tensile strain, wafer 2U may have a warpage, with the center portion of the wafer 2U being lower than the edge portions of the wafer 2L. Depending on the size of the wafer 2U and the strain applied by dielectric layer 28U, the height difference DH2 may be in the range between about 1 μm and about 20 μm.

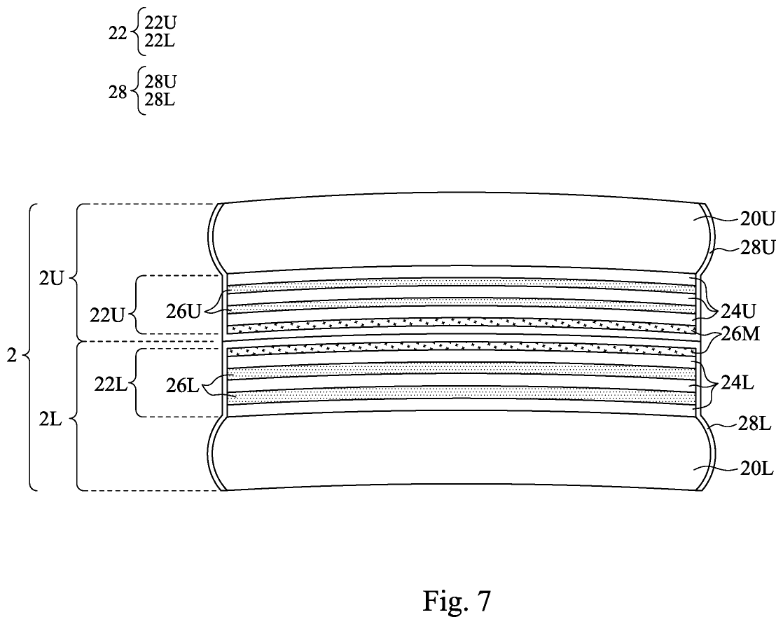

In FIG. 7, wafer 2U is bonded to wafer 2L through fusion bonding, wherein Si—O—Si bonds are formed to join dielectric layer 28U to dielectric layer 28L. The respective process is illustrated as process 210 in the process flow 200 as shown in FIG. 20. The bonding process may include a pre-bonding process and an annealing process following the pre-bonding process. In accordance with some embodiments, during the pre-bonding, the center of wafer 2U is put into contact with the center of wafer 2L, and the contacting is propagated to the edges of wafers 2U and 2L.

After the pre-bonding, an annealing process is performed, for example, with Si—O—Si bonds being formed between dielectric layers 28U and 28L, so that dielectric layers 28U and 28L are bonded to each other with high bonding strength. Dielectric layers 28U and 28L are thus alternatively referred to as bond layers. Composite wafer 2 is thus formed, as shown in FIG. 7. Throughout the description, dielectric layers 28U and 28L are collectively referred to as dielectric layers (bond layers) 28. Multilayer stacks 22U and 22L are collectively referred to as multilayer stack 22.

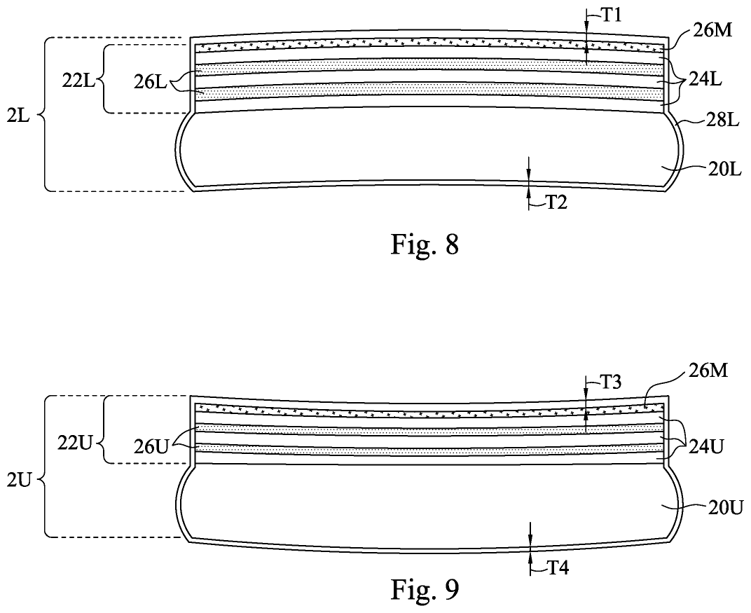

FIGS. 8-10 illustrate the formation and the bonding of wafers 2U and 2L to form composite wafer 2 in accordance with alternative embodiments. These embodiments are similar to the embodiments as shown in FIGS. 1-7, except that dielectric layers 28L and 28U also include bottom portions underlying the respective wafers 2L and 2U, respectively. The structures, the materials, and the formation processes in accordance with these embodiments are essentially the same as discussed referring to FIGS. 1 through 7, and thus the details are not repeated herein.

Referring to FIG. 8, wafer 2L, multilayer stack 22L, and dielectric layer 28L are formed. Dielectric layer 28L may include top portions over multilayer stack 22L, sidewall portions on the sidewalls of multilayer stack 22L and substrate 20L, and a bottom portion underlying substrate 20L. In accordance with some embodiments, the thickness T1 of the top portion is greater than the thickness T2 of the bottom portion. In accordance with alternative embodiments, thickness T1 is equal to thickness T2. The formation of the bottom portion may reduce the warpage of the wafer 2L. Making thickness T1 to be equal to thickness T2 may eliminate or reduce the warpage of the wafer 2L.

Referring to FIG. 9, wafer 2U, multilayer stack 22U, and dielectric layer 28U are formed. Dielectric layer 28U may include top portions over multilayer stack 22U, sidewall portions on the sidewalls of multilayer stack 22U and substrate 20U, and a bottom portion underlying substrate 20U. In accordance with some embodiments, the thickness T3 of the top portion is greater than the thickness T4 of the bottom portion. In accordance with alternative embodiments, thickness T3 is equal to thickness T4. The formation of the bottom portion may reduce the warpage of the wafer 2U. Making thickness T3 to be equal to thickness T4 may eliminate or reduce the warpage of the wafer 2U.

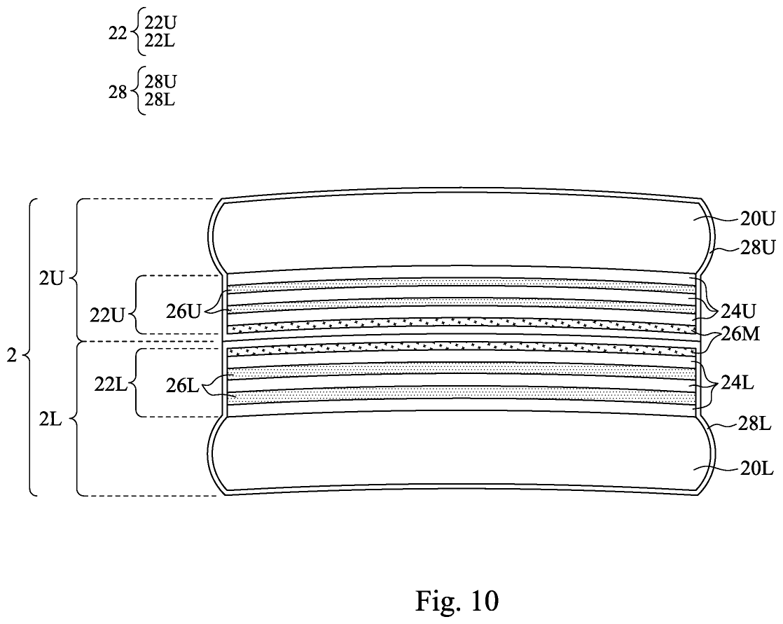

FIG. 10 illustrates the bonding of wafer 2U to wafer 2L to form composite wafer 2. The bonding process may be essentially the same as discussed referring to FIG. 7, and is not repeated herein.

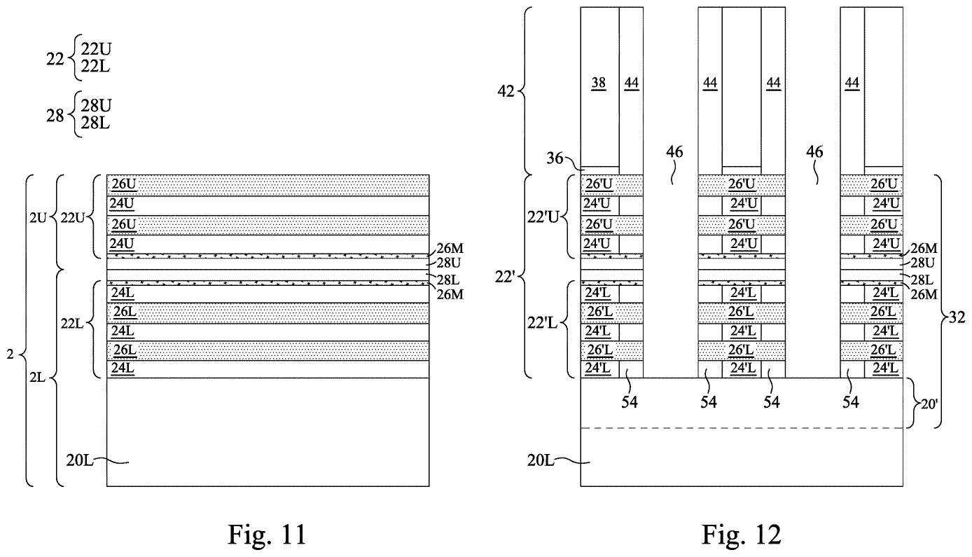

FIGS. 11 through 17 illustrate the formation of CFETs based on composite wafer 2 in accordance with some embodiments. FIG. 11 illustrates a portion of wafer 2 as shown in FIG. 7 or 10 in accordance with some embodiments.

In accordance with some embodiments, the substrate 20U is thinned, and a remaining portion of substrate 20U forms a top semiconductor layer 26U, which overlies the topmost dummy semiconductor layer 24U.

Referring to FIG. 12, in a subsequent process, multilayer stacks 22U and 22L and substrate 20 are patterned to form semiconductor strips 32. The respective process is illustrated as process 212 in the process flow 200 as shown in FIG. 20. Each of semiconductor strips 32 includes semiconductor strip 20′ (the portions of the original substrate 20) and multilayer stack 22′, which includes the patterned remaining portions of multilayer stacks 22U and 22L. The remaining portions 22′ of multilayers stack 22 are referred to as nanostructures hereinafter, which are referred to using the corresponding reference number followed by a “′” sign. Accordingly, multilayer stack 22′ includes dummy nanostructures 24′, lower semiconductor nanostructures 26′L, middle semiconductor nanostructures 26′M, and upper semiconductor nanostructures 26′U. The patterning may be anisotropic. The lower semiconductor nanostructures 26′L and the upper semiconductor nanostructures 26′U may further be collectively referred to as semiconductor nanostructures 26′.

The lower semiconductor nanostructures 26′L will act as the channel regions for lower nanostructure-FETs of the CFETs. The upper semiconductor nanostructures 26′U will act as the channel regions for upper nanostructure-FETs of the CFETs. The middle semiconductor nanostructures 26′M are the semiconductor nanostructures 26′ that are immediately above/below (e.g., in contact with) dielectric layers 28. The middle semiconductor nanostructures 26′M may be used for isolation and may or may not act as channel regions for the CFETs. The isolation structures and the middle semiconductor nanostructures 26′M may define boundaries of the lower nanostructure-FETs and the upper nanostructure-FETs.

Isolation regions (Shallow Trench Isolation (STI) regions, not shown) are formed over the substrate 20 and between adjacent semiconductor strips 32. The isolation regions are not in the illustrated cross-section, and thus are not shown. The isolation regions may include a dielectric liner and a dielectric material over the dielectric liner. The isolation regions are then recessed. Some upper portions of semiconductor strips 32 (including multilayer stacks 22′) protrude higher than the remaining the isolation regions to form protruding fins.

Further referring to FIG. 12, dummy gate stacks 42 are formed on the top surfaces and the sidewalls of the protruding fins. The respective process is illustrated as process 214 in the process flow 200 as shown in FIG. 20. Each of dummy gate stacks 42 may include dummy dielectric layer 36, dummy gate layer 38, and mask layer 40. Dummy dielectric layer 36 may be formed of or comprise, for example, silicon oxide, silicon nitride, a combination thereof, or the like. The material of dummy gate layer 38 may be conductive or non-conductive, and may be selected from a group including amorphous silicon, polycrystalline-silicon (polysilicon), poly-crystalline silicon-germanium (poly-SiGe), or the like. Mask layer 40 is formed over the planarized dummy gate layer 38, and may include, for example, silicon nitride, silicon oxynitride, or the like.

The mask layer 40 may be patterned through photolithography and etching processes to form a mask, which is then used to etch and pattern dummy gate layer 38, and possibly dummy dielectric layer 36. The remaining portions of mask layer 40, dummy gate layer 38, and dummy dielectric layer 36 form dummy gate stacks 42.

Gate spacers 44 are formed over the multilayer stacks 22′ and on the exposed sidewalls of dummy gate stacks 42. The respective process is illustrated as process 216 in the process flow 200 as shown in FIG. 20. The applicable dielectric materials may include silicon oxide, silicon nitride, silicon oxynitride, silicon oxy-carbo-nitride, or the like, which may be formed by a deposition process such as CVD, ALD, or the like.

As further shown in FIG. 12, source/drain recesses 46 are formed in semiconductor strips 32. The respective process is illustrated as process 218 in the process flow 200 as shown in FIG. 20. The source/drain recesses 46 are formed through etching, and may extend through the multilayer stacks 22′. The bottom surfaces of the source/drain recesses 46 may be at a level above, below, or level with the top surfaces of the isolation regions, which are not in the illustrated cross-section. In the etching processes, the gate spacers 44 and the dummy gate stacks 42 mask some portions of the semiconductor strips 32.

Dummy nanostructures 24′U and 24′L are also laterally recessed, and a dielectric material is filled into the respective recesses to form inner spacers 54, which are dielectric spacers.

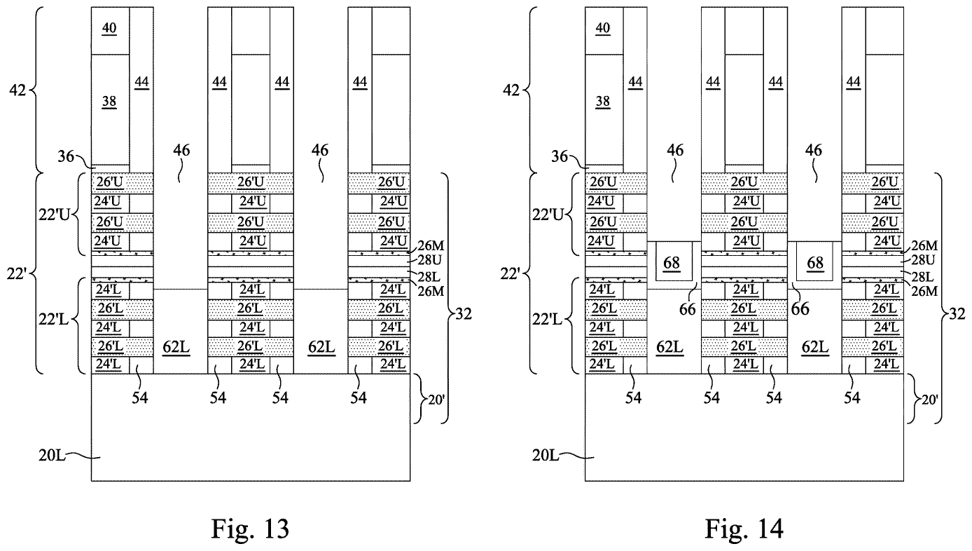

Referring to FIG. 13, lower epitaxial source/drain regions 62L are formed in the lower portions of the source/drain recesses 46. The respective process is illustrated as process 220 in the process flow 200 as shown in FIG. 20. The lower epitaxial source/drain regions 62L are in contact with the lower semiconductor nanostructures 26′L and are not in contact with the upper semiconductor nanostructures 26′U. Inner spacers 54 electrically insulate the lower epitaxial source/drain regions 62L from the dummy nanostructures 24′L, which will be replaced with replacement gates in subsequent processes.

The lower epitaxial source/drain regions 62L are epitaxially grown, and have a conductivity type that is suitable for the device type (p-type or n-type) of the lower nanostructure-FETs. When lower epitaxial source/drain regions 62L are p-type source/drain regions, the respective material may include silicon or silicon germanium, which is doped with a p-type dopant such as boron, indium, or the like. The corresponding dielectric layer 28L has a compressive strain.

When lower epitaxial source/drain regions 62L are n-type source/drain regions, the respective material may include silicon or carbon-doped silicon, which is doped with an n-type dopant such as phosphorous, arsenic, or the like. The corresponding dielectric layer 28L has a tensile strain.

Referring to FIG. 14, a first contact etch stop layer (CESL) 66 and a first ILD 68 are formed. The respective process is illustrated as process 222 in the process flow 200 as shown in FIG. 20. The first CESL 66 may be formed of a dielectric material having a high etching selectivity from the etching of the first ILD 68, such as silicon nitride, silicon oxide, silicon oxynitride, or the like, which may be formed by any suitable deposition process, such as CVD, ALD, or the like. The first ILD 68 may be formed of a dielectric material. The applicable dielectric material of the first ILD 68 may include phospho-silicate glass (PSG), boro-silicate glass (BSG), boron-doped phospho-silicate glass (BPSG), undoped silicate glass (USG), silicon oxide, or the like.

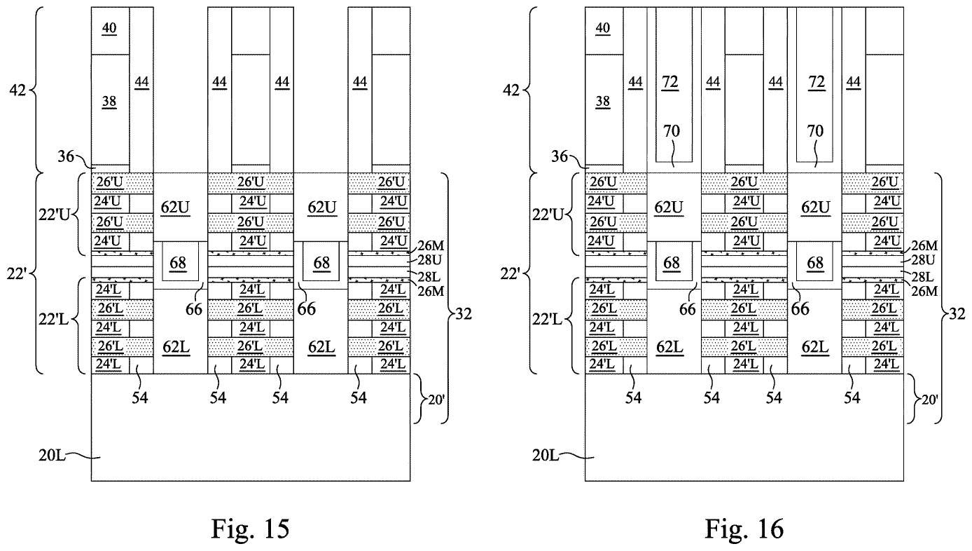

Next, as shown in FIG. 15, upper epitaxial source/drain regions 62U are formed in the upper portions of the source/drain recesses 46. The respective process is illustrated as process 224 in the process flow 200 as shown in FIG. 20. The materials of upper epitaxial source/drain regions 62U may be selected depending on the desired conductivity type of upper epitaxial source/drain regions 62U.

The conductivity type of the upper epitaxial source/drain regions 62U may be opposite the conductivity type of the lower epitaxial source/drain regions 62L. Alternatively stated, the upper epitaxial source/drain regions 62U may be oppositely doped from the lower epitaxial source/drain regions 62L. When upper epitaxial source/drain regions 62U are n-type regions, the corresponding dielectric layer 28U has a tensile strain. Conversely, when upper epitaxial source/drain regions 62U are p-type regions, the corresponding dielectric layer 28U has a compressive strain.

Referring to FIG. 16, a second CESL 70 and a second ILD 72 are formed. The respective process is illustrated as process 226 in the process flow 200 as shown in FIG. 20. The materials and the formation methods may be similar to the materials and the formation methods of first CESL 66 and first ILD 68, respectively, and are not repeated in detail herein. The formation process may include depositing the layers for CESL 70 and ILD 72, and performing a planarization process to remove the excess portion of the corresponding layers. After the planarization process, thee top surfaces of the second ILD 72, the gate spacers 44, and the dummy gate stacks 42 are coplanar (within process variations). The planarization process may remove masks 40, or leave hard masks 40 unremoved.

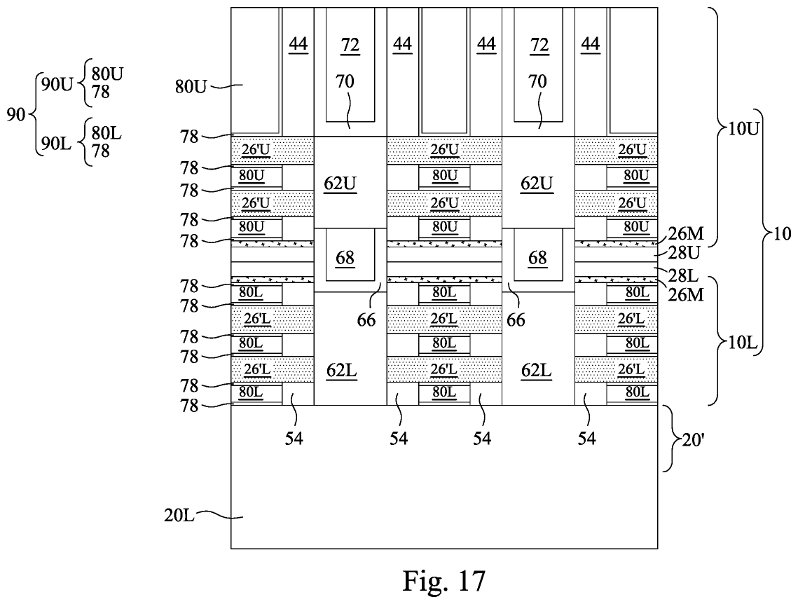

The dummy gate stacks 42 are then removed in one or more etching processes, and replacement gate stacks 90 (including gate stacks 90L and 90U) are formed in the respective recesses, as shown in FIG. 17. The respective processes are illustrated as process 228 in the process flow 200 as shown in FIG. 20. Gate stacks 90L include gate dielectrics 78 and gate electrodes 80L. Gate stacks 90U include gate dielectrics 78 and gate electrodes 80U. Each of gate dielectrics 78 may include an interfacial layer (such as a silicon oxide layer) and a high-k dielectric layer over the interfacial layer. Lower FET 10L and upper FET 10U are thus formed, which collectively form CFET 10.

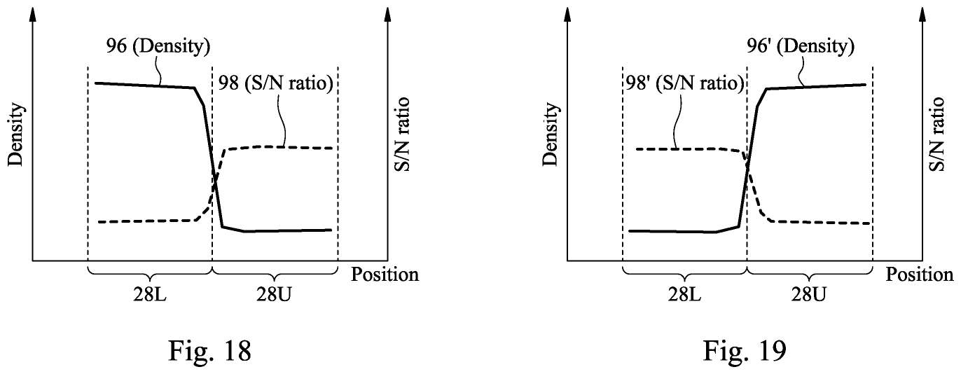

FIG. 18 illustrates the properties of dielectric layers 28L and 28U in accordance with some embodiments. The X-axis illustrates the positions along the arrow 94 in FIG. 17, wherein dielectric layers 28L and 28U are illustrated. The left Y-axis shows the density of dielectric layers 28L and 28U, and the right Y-axis shows the silicon-to-nitrogen (S/N) atomic ratios of dielectric layers 28L and 28U. The left Y-axis corresponds to line 96. As shown by line 96, the density decreases from dielectric layer 28L to dielectric layer 28U. The right Y-axis corresponds to line 98. As shown by line 98, the Si/N atomic ratio of dielectric layers 28 increase from dielectric layer 28L to dielectric layer 28U.

It is appreciated that the values shown in FIG. 18 correspond to the CFET in which the lower FETs are PFETs and the upper FETs are NFETs. In accordance with alternative embodiments in which the lower FETs are NFETs and the upper FETs are PFETs, the density is shown in FIG. 19. As shown by line 96′ in FIG. 19, the density increases from dielectric layer 28L to dielectric layer 28U. As shown by line 98′, the Si/N atomic ratio of dielectric layers 28 decreases from dielectric layer 28L to dielectric layer 28U.

The embodiments of the present disclosure have some advantageous features. By using bond layers to apply compressive strain to the channels of the PFETs and tensile strain to the channels of the NFETs, the strain is increased to be higher than using source/drain regions alone to apply strain. The drive currents of both of NFETs and PFETs can be increased.

In accordance with some embodiments of the present disclosure, a method comprises forming a first wafer comprising forming a first semiconductor layer over a first substrate; and depositing a first dielectric layer comprising a first top portion over the first semiconductor layer, wherein the first dielectric layer comprises a first dielectric material; forming a second wafer comprising forming a second semiconductor layer over a second substrate; and depositing a second dielectric layer comprising a second top portion over the second semiconductor layer, wherein the second dielectric layer comprises a second dielectric material different from the first dielectric material; bonding the second wafer to the first wafer to form a composite wafer, wherein the first dielectric layer is bonded to and joined to the second dielectric layer; and forming a complementary field-effect transistor based on the composite wafer.

In an embodiment, the depositing the first dielectric layer and the depositing the second dielectric layer comprise same elements, and are performed using different process conditions. In an embodiment, the first dielectric layer and second first dielectric layer comprise silicon nitride, and wherein the depositing the first dielectric layer is performed using a first silicon-containing precursor and a first nitrogen-containing precursor; and the depositing the second dielectric layer is performed using a second silicon-containing precursor and a second nitrogen-containing precursor, wherein a first flow rate ratio of the first silicon-containing precursor to the first nitrogen-containing precursor is smaller than a second flow rate ratio of the second silicon-containing precursor to the second nitrogen-containing precursor.

In an embodiment, the depositing the first dielectric layer comprises a first wafer-cooling process having a first wafer temperature dropping rate, and the depositing the second dielectric layer comprises a second wafer-cooling process having a second wafer temperature dropping rate, and the second wafer temperature dropping rate is lower than the first wafer temperature dropping rate. In an embodiment, the first dielectric layer has a first density, and the second dielectric layer has a second density smaller than the first density.

In an embodiment, a first part of the first semiconductor layer is formed as a first channel of a p-type transistor in the complementary field-effect transistor, wherein the first dielectric layer applies a compressive strain to the first semiconductor layer; and a second part of the second semiconductor layer is formed as a second channel of an n-type transistor in the complementary field-effect transistor, wherein the second dielectric layer applies a tensile strain to the second semiconductor layer. In an embodiment, after the complementary field-effect transistor is formed, the first dielectric layer and the second dielectric layer are between the p-type transistor and the n-type transistor.

In an embodiment, when the first dielectric layer is deposited, the first dielectric layer further comprises a first sidewall portion on a sidewall of the first semiconductor layer. In an embodiment, the first dielectric layer further comprises a first bottom portion underlying the first substrate. In an embodiment, when the second dielectric layer is deposited, the second dielectric layer further comprises a second sidewall portion on a second sidewall of the second semiconductor layer. In an embodiment, the second dielectric layer further comprises a second bottom portion underlying the second substrate.

In accordance with some embodiments of the present disclosure, a method comprises forming a first wafer comprising depositing a first plurality of semiconductor layers over a first substrate; and depositing a first dielectric layer as a part of the first wafer, wherein the first dielectric layer is configured to apply a compressive strain to the first plurality of semiconductor layers; forming a second wafer comprising forming a second plurality of semiconductor layers over a second substrate; and depositing a second dielectric layer as a part of the second wafer, wherein the second dielectric layer is configured to apply a tensile strain to the second plurality of semiconductor layers; bonding the second wafer to the first wafer to form a composite wafer, wherein the first dielectric layer is bonded to and joined to the second dielectric layer; and forming a complementary field-effect transistor comprising a p-type transistor comprising first parts of the first plurality of semiconductor layers as a first channel; and an n-type transistor comprising second parts of the second plurality of semiconductor layers as a second channel.

In an embodiment, the first dielectric layer has a first density, and the second dielectric layer has a second density smaller than the first density. In an embodiment, both of the first dielectric layer and the second dielectric layer comprise silicon nitride. In an embodiment, the first dielectric layer has a first silicon-to-nitrogen atomic ratio, and the second dielectric layer has a second silicon-to-nitrogen atomic ratio greater than the first silicon-to-nitrogen atomic ratio. In an embodiment, the depositing the first dielectric layer comprises a first wafer-cooling process having a first wafer temperature dropping rate, and the depositing the second dielectric layer comprises a second wafer-cooling process having a second wafer temperature dropping rate, and the second wafer temperature dropping rate is smaller than the first wafer temperature dropping rate.

In accordance with some embodiments of the present disclosure, a method comprises forming a complementary field-effect transistor structure comprising forming a p-type transistor comprising a first channel region; and a first source/drain region aside of the first channel region; forming a first dielectric layer, wherein the first dielectric layer overlaps the first channel region, and wherein the first dielectric layer comprises a first dielectric material; forming a second dielectric layer, wherein the second dielectric layer is over and joined with the first dielectric layer, and wherein the second dielectric layer comprises a second dielectric material different from the first dielectric material; and forming an n-type transistor over the second dielectric layer, the n-type transistor comprising a second channel region; and a second source/drain region aside of the second channel region.

In an embodiment, the first dielectric layer has a higher density than the second dielectric layer. In an embodiment, both the first dielectric layer and the second dielectric layer comprise silicon nitride, and wherein the first dielectric layer has a first silicon-to-nitrogen atomic ratio, and the second dielectric layer has a second silicon-to-nitrogen atomic ratio greater than the first silicon-to-nitrogen atomic ratio. In an embodiment, each of the first dielectric layer and the second dielectric layer has a thickness in a range between about 5 nm and about 20 nm.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming a first wafer comprising:
forming a first semiconductor layer over a first substrate; and
depositing a first dielectric layer comprising a first top portion over the first semiconductor layer, wherein the first dielectric layer is deposited using first process conditions;
forming a second wafer comprising:
forming a second semiconductor layer over a second substrate; and
depositing a second dielectric layer comprising a second top portion over the second semiconductor layer, wherein the second dielectric layer is deposited using second process conditions different from the first process conditions, and wherein the first dielectric layer and the second dielectric layer comprise same elements;
bonding the second wafer to the first wafer to form a composite wafer, wherein the first dielectric layer is bonded to and joined to the second dielectric layer; and
forming a complementary field-effect transistor based on the composite wafer.

2. The method of claim 1, wherein the same elements comprise silicon and nitride.

3. The method of claim 2, wherein:
the first dielectric layer is deposited using a first silicon-containing precursor and a first nitrogen-containing precursor having a first flow rate ratio of the first silicon-containing precursor to the first nitrogen-containing precursor; and
the second dielectric layer is deposited using a second silicon-containing precursor and a second nitrogen-containing precursor, wherein a second flow rate ratio of the second silicon-containing precursor to the second nitrogen-containing precursor is greater than the first flow rate ratio.

4. The method of claim 1, wherein the first dielectric layer has a first silicon-to-nitrogen atomic ratio, and the second dielectric layer has a second silicon-to-nitrogen atomic ratio greater than the first silicon-to-nitrogen atomic ratio.

5. The method of claim 1, wherein the depositing the first dielectric layer comprises a first wafer-cooling process having a first wafer temperature dropping rate, and the depositing the second dielectric layer comprises a second wafer-cooling process having a second wafer temperature dropping rate lower than the first wafer temperature dropping rate.

6. The method of claim 1, wherein the first dielectric layer has a first density, and the second dielectric layer has a second density smaller than the first density.

7. The method of claim 1, wherein:
a first part of the first semiconductor layer is formed as a first channel of a p-type transistor in the complementary field-effect transistor, wherein the first dielectric layer applies a compressive strain to the first semiconductor layer; and
a second part of the second semiconductor layer is formed as a second channel of an n-type transistor in the complementary field-effect transistor, wherein the second dielectric layer applies a tensile strain to the second semiconductor layer.

8. The method of claim 7, wherein after the complementary field-effect transistor is formed, the first dielectric layer and the second dielectric layer are between the p-type transistor and the n-type transistor.

9. The method of claim 1, wherein when the first dielectric layer is deposited, the first dielectric layer further comprises a first sidewall portion on a sidewall of the first semiconductor layer.

10. The method of claim 9, wherein the first dielectric layer further comprises a first bottom portion underlying the first substrate.

11. The method of claim 1, wherein when the second dielectric layer is deposited, the second dielectric layer further comprises a second sidewall portion on a second sidewall of the second semiconductor layer.

12. The method of claim 11, wherein the second dielectric layer further comprises a second bottom portion underlying the second substrate.

13. A method comprising:
forming a first wafer comprising:
depositing a first plurality of semiconductor layers over a first substrate; and
depositing a first bond layer on the first plurality of semiconductor layers, wherein the first bond layer comprises silicon nitride;
forming a second wafer comprising:
forming a second plurality of semiconductor layers over a second substrate; and
depositing a second bond layer on the second plurality of semiconductor layers, wherein the second bond layer comprises silicon nitride, wherein the first bond layer and the second bond layer have different properties selected from the group consisting of different densities, different Si-to-N atomic ratios, and combinations thereof;
bonding the second wafer to the first wafer to form a composite wafer, wherein the first bond layer is bonded to and joined to the second bond layer; and
forming a complementary field-effect transistor comprising:
a p-type transistor comprising first parts of the first plurality of semiconductor layers as a first channel; and
an n-type transistor comprising second parts of the second plurality of semiconductor layers as a second channel.

14. The method of claim 13, wherein the different properties comprise different densities.

15. The method of claim 14, wherein a first density of the first bond layer is greater than a second density of the second bond layer.

16. The method of claim 13, wherein the different properties comprise different Si-to-N atomic ratios.

17. The method of claim 16, wherein a first Si-to-N atomic ratio of the first bond layer is smaller than a second Si-to-N atomic ratio of the second bond layer.

18. The method of claim 13, wherein the silicon nitride of the first bond layer is deposited using first process conditions, and wherein the silicon nitride of the second bond layer is deposited using second process conditions different from the first process conditions.

19. A method comprising:
forming a first wafer comprising:
depositing a first plurality of semiconductor layers over a first substrate; and
depositing a first bond layer over the first plurality of semiconductor layers, wherein the first bond layer results in the first wafer to have a greater warpage than before the first bond layer is deposited;
forming a second wafer comprising:
forming a second plurality of semiconductor layers over a second substrate; and
depositing a second bond layer over the second plurality of semiconductor layers, wherein the second bond layer results in the second wafer to have a greater warpage than before the second bond layer is deposited; and
bonding the second wafer to the first wafer, with the first bond layer being bonded to the second bond layer, and wherein the first wafer and the second wafer are warped in a same direction.

20. The method of claim 19, wherein the first bond layer and the second bond layer comprise silicon nitride.
